(19) United States
(12) Patent Application Publication
(10) Pub. No.: US 2003/0077524 A1
(43) Pub. Date: Apr. 24, 2003

(54) Method of repairing pattern of phase shift mask and phase shift mask repaired using the same

(76) Inventor: Yo-han Choi, Yongin-city (KR)

Correspondence Address: VOLENTINE FRANCOS, P.L.L.C., Suite 150, 12200 Sunrise Valley Drive, Reston, VA, 20191, US

(21) Appl. No.: 10/272,008

(22) Filed: Oct. 17, 2002

(30) Foreign Application Priority Data
Oct. 23, 2001 (KR) 01-65444

(51) Int. Cl. G03F 9/00; C23C 14/00; C23C 14/32; G03C 5/00; G03C 3/02

(52) U.S. Cl. 430/5; 430/322; 430/323; 430/324; 204/192.1; 204/192.34

(57) ABSTRACT

A mask pattern of a phase shift mask for use in photolithography is repaired. First, an imaginary correction pattern is devised according to the pattern of a mask layer that is disposed on the surface of a transparent plate constituting the body of the mask. The surface of the mask body is etched to a predetermined depth according to the imaginary correction pattern, at a location adjacent the mask layer, to thereby form a recess in the mask body. A phase shifter having a predetermined thickness is then formed by depositing phase shifting material in the recess.

### BACKGROUND OF THE INVENTION

1. Field of the Invention

The present invention relates to a photolithographic process used in manufacturing semiconductor devices. More particularly, the present invention relates to a phase shift mask and to a method of repairing a phase shift mask.

2. Description of the Related Art

As semiconductor devices become highly integrated, the distance between various elements of the devices decreases, and the line width of the devices becomes extremely fine. Photolithography is a process essential to creating the fine patterns required of highly integrated semiconductor devices. In photolithography, the type of light source used in a stepper, i.e., in the alignment exposure apparatus, as well as the type of mask that is used to transcribe the patterns onto a semiconductor wafer, depend on the design rule for the line width. In particular, when a semiconductor device is manufactured to create a fine pattern according to a design rule of less than 0.3 μm, light having a high wavelength, such as ultra violet (UV) or that emitted by an excimer laser, is used instead of conventional I-line light. Also, a phase shift mask is used to transfer or transcribe a fine pattern onto the wafer.

The phase shift mask employs what is referred to as a shifter to form very fine patterns on the wafer. By using such a shifter to create a phase shift in light transmitted through the mask, a phase shift mask can form patterns that are finer than those that can be formed using a conventional mask even if the pattern of the phase shift mask is formed according to the same design rule as the conventional mask. However, errors or defects may occur in a process of forming a pattern of the phase shift mask. In this case, the quartz substrate of the mask is etched to a predetermined depth to repair the pattern.

Nonetheless, it is not always possible to etch the substrate deep enough to attain the same phase shift as provided by that portion of the pattern adjacent the etched portion. That is, it is not easy to create the desired shape of the repaired pattern. The repair process itself can thus result in creating errors in the phase shift.

### SUMMARY OF THE INVENTION

An object of the present invention is to solve the above-described problems of the prior art. More specifically, it is an object of the present invention to provide a method of repairing a phase shift mask pattern, and which method is reliable and easy to carry out. Likewise, it is an object of the present invention to provide a repaired phase shift mask that produces a desired phase shifting effect.

According to one aspect of the present invention, a method of repairing a phase shift mask pattern includes an initial step of devising an imaginary correction pattern based on the configuration of the phase shift mask under repair, namely based on the configuration of the pattern of a mask layer formed on the surface of a transparent, e.g. quartz, plate (the body of the mask). The surface of the plate is then etched to a predetermined depth, according to the imaginary correction pattern, at a location adjacent the mask layer. A shifter is then formed in the recess by depositing phase-shifting material to a predetermined thickness in the recess.

In devising the imaginary correction pattern, the pattern of the mask layer is scanned with the light subsequently used in the actual physical repairing of the mask pattern, whereby an image of the pattern of the mask layer is discerned. The discerned image of the pattern of the mask layer is compared with a predetermined memorized ideal pattern. The difference between the memorized pattern and the discerned pattern is recognized as the correction pattern.

When etching the mask body, an etch gas is used to form an etch gas atmosphere over the mask. A focused ion beam (FIB) is directed through the atmosphere and onto a portion of the mask body corresponding to the imaginary correction pattern. The FIB is scanned across what corresponds to the top of the imaginary correction pattern. Accordingly, a reaction takes place, whereby the recess is etched in a portion of the mask body corresponding to the imaginary correction pattern.

To form the phase shifter in the recess, an induction beam is emitted into the recess. A deposition source material is sprayed onto the trace of the induction beam. Preferably, the deposition source material is a hydrocarbon (CₓH_{y}). In this case, the deposition source material is dissociated into particles of carbon on the order of microns in diameter, i.e., fine carbon powder. The material consequently deposited on the mask body to form the shifter is a GaₓC_{y} compound.

Alternatively, the shifter may comprise an MoSiOₓN_{y} compound or CrF₂.

According to another aspect of the present invention, the resulting (repaired) phase shift mask includes a mask body in the form of a plate of a transparent material (preferably, quartz), an opaque mask layer disposed on a surface of the mask body, and a correction pattern adjacent the opaque mask layer. The correction pattern includes a recess in the mask body, and a shifter of phase shifting material having a predetermined thickness and situated in the recess of the mask body.

The present invention as featured above provides for a large process margin for the thickness of the phase shifter so that the correction pattern can provide a necessary degree of phase shifting. Also, according to the present invention, the pattern of the phase shift mask can be successfully and easily repaired.

### BRIEF DESCRIPTION OF THE DRAWINGS

The above and other objects, features and advantages of the present invention will become more apparent from the following detailed description of the preferred embodiments thereof made with reference to the attached drawings, of which:

FIG. 1A is a perspective view of a section of a phase shift mask repaired using a method according to the present invention;

FIG. 1B is a flow chart of a method of repairing a phase shift mask pattern according to the present invention;

FIG. 2 is a perspective view of a section of a phase shift mask to be repaired by a method according to the present invention;

FIG. 3 is a sectional view of the phase shift mask shown in FIG. 2, as taken along line I-I;

FIGS. 4A through 4C and FIGS. 5A through 5B are sectional views of the phase shift mask, respectively, illustrating the method of repairing a phase shift mask pattern in accordance with the present invention;

FIG. 6 is a perspective view of a section of a partially repaired phase shift mask according to the present invention;

FIG. 7A is an SEM (scanning electron microscope) photograph of contact patterns formed on a photoresist using a phase shift mask having a phase shift pattern repaired according to the present invention;

FIG. 7B is an SEM photograph of the repaired phase shift pattern used to form the contact patterns shown in FIG. 7A;

FIG. 7C is an SEM photograph of contact patterns formed on a photoresist using a phase shift mask having a phase shift pattern repaired according to the conventional method;

FIG. 7D is an SEM photograph of the repaired phase shift pattern used to form the contact patterns shown in FIG. 7C; and

FIGS. 8A and 8B are schematic diagrams of the same contact patterns shown in FIGS. 7A and 7C, respectively.

### DETAILED DESCRIPTION OF THE PREFERRED EMBODIMENTS

The present invention will be described more fully hereinafter with reference to the accompanying drawings.

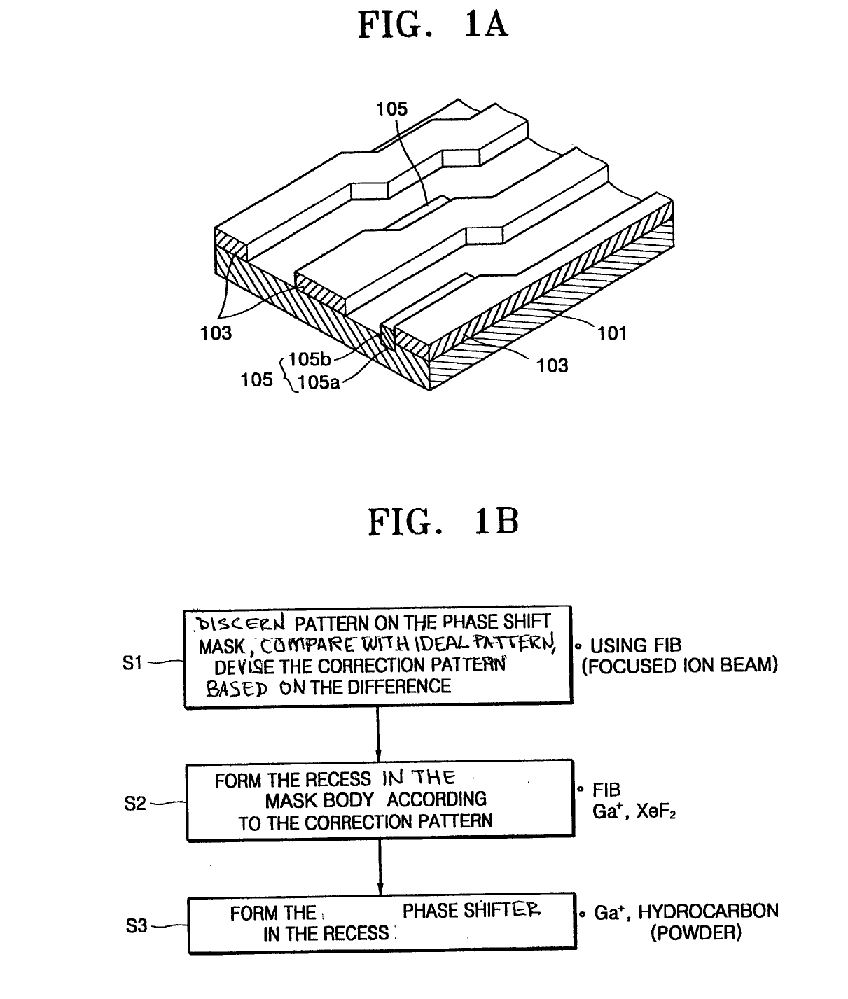

Referring first to FIG. 1A, the phase shift mask is generally plate-shaped for use as a reticle in a photolithographic process. The phase shift mask repaired according to the present invention includes a mask substrate or body 101 comprising a plate of transparent material, a mask layer 103 that is formed on at least one surface of the mask body 101 and has a pattern configured according to the photolithographic process to be performed, and a correction pattern 105 that is in contact with the opaque mask layer 103.

The mask body 101 is formed of quartz through which light can be completely transmitted, is rectangular and has a predetermined thickness. Also, there should be no defects on the surface of the mask body 101 so that light is transmitted therethrough without any phase difference.

The opaque mask layer 103 comprises patterns of chromium (Cr) and chromium oxide (Cr₂O₅) which block light completely. Thus, light emitted onto the phase shift mask including the mask layer 103 is selectively transmitted therethrough, i.e., through the exposed portions of the transparent mask body 101 but not through the opaque patterns of the mask layer 103. The mask layer 103 further includes a phase shifter for forming an extremely fine pattern on a wafer. The phase shifter comprises a pattern of partially opaque material.

The correction pattern 105 is in contact with the mask layer 103 so as to repair errors in the originally formed pattern of the mask layer 103. The correction pattern 105 comprises a phase shifter 105b situated in a recess 105a in the mask body 101. The phase shifter 105b is preferably formed of a GaₓC_{y} compound. However, MoSᵢOₓN_{y} or CrF₂ may also be used as the material of the shifter 105a.

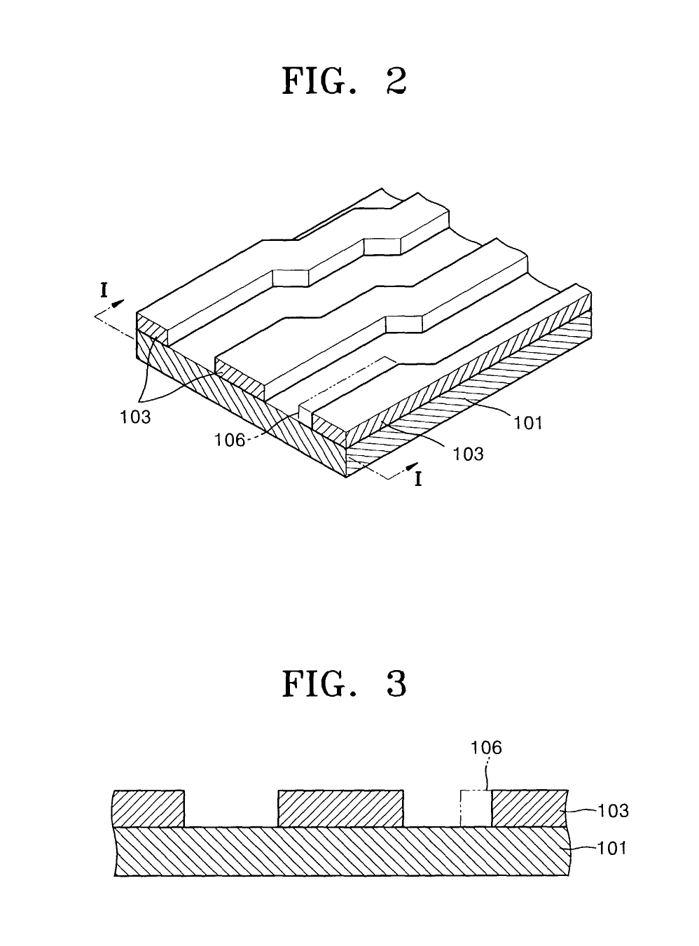

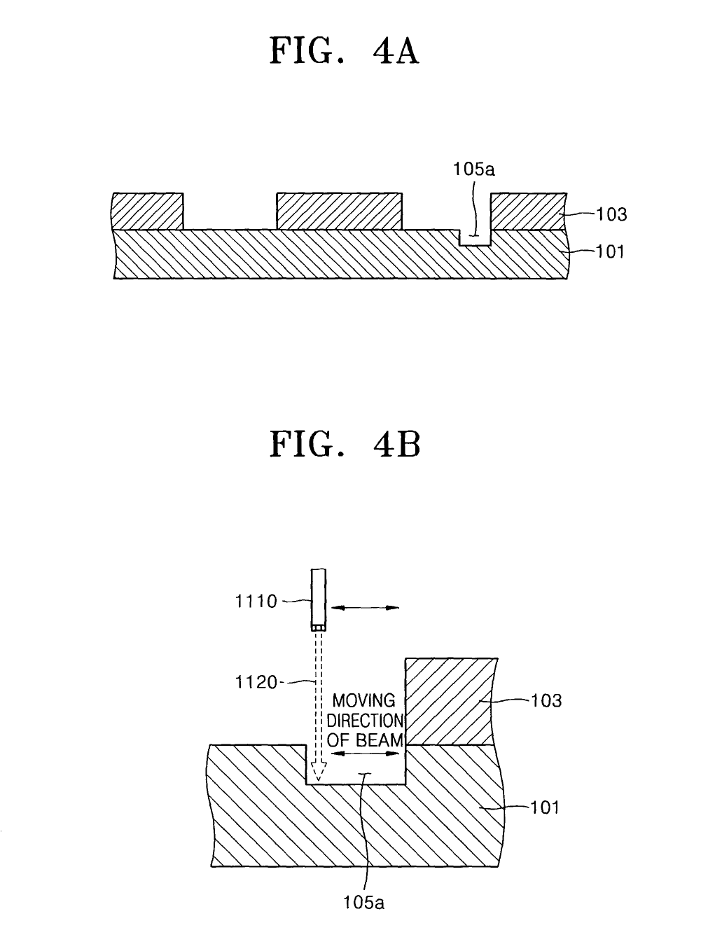

FIG. 1B is illustrates the basic steps in a method for repairing a phase shift mask pattern according to the present invention. FIGS. 2 and 3 show a phase shift mask to be repaired according to the present invention. The method will be described generally with reference to these figures.

First, the phase shift mask is placed on an apparatus for use in repairing the pattern of the mask layer 103. The phase shift mask is then scanned with light of a predetermined type, whereby the pattern of the mask layer 103 is discerned. The phase shift mask pattern is compared with a previously memorized ideal mask pattern. Accordingly, an imaginary correction pattern 106 is devised next to the portion of the mask layer 103 requiring repair, as shown in FIGS. 2 and 3 (step S1).

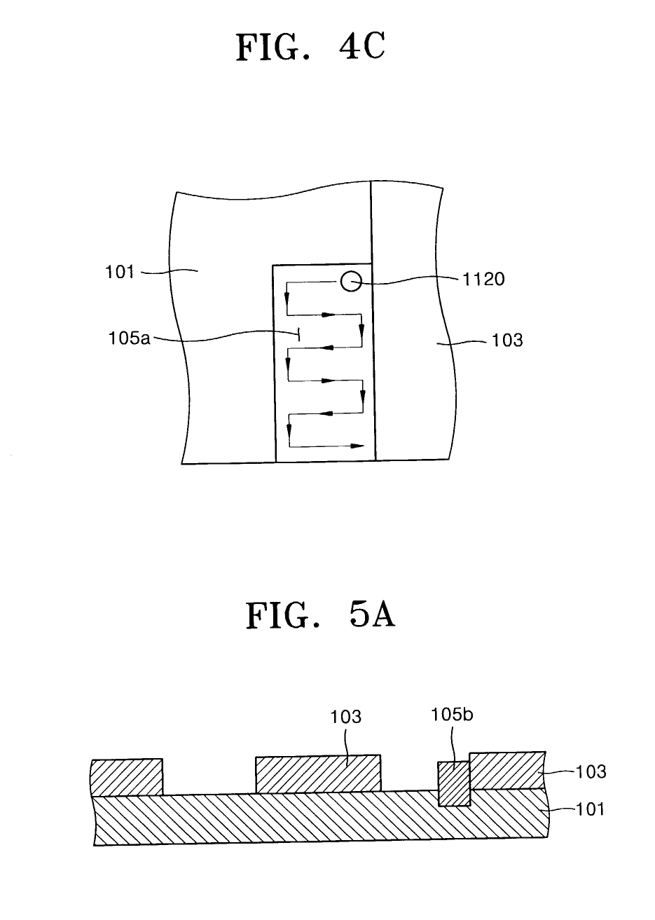

Referring to FIGS. 4A through 4C, which illustrate step S2 of FIG. 1B, the shape of the imaginary correction pattern 106 is transferred to the surface of the mask body 101, by an apparatus for repairing the mask pattern, e.g., a focused ion beam (FIB) system. Thus, the recess 105a is formed in the mask body 101. More specifically, a focused ion beam (FIB) (1120 of FIG. 4B) is emitted onto the transparent mask body 101 and the mask body 101 is etched by the beam using a spot etch method to thereby form the recess 105a to a predetermined depth in the surface of the mask body 101.

Still referring to FIG. 4B, an etch gas of XeF₂ is directed to the surface of the mask body 101 to form an etch gas atmosphere, and an FIB 1120 of gallium ions (Ga+) is emitted toward the region in which the correction pattern 105 is to be formed. The FIB 1120 formed of gallium ions (Ga+) has a spot diameter of several tens of nm. A high temperature atmosphere formed within this spot instantly heats the portion of the mask body 101 irradiated by the beam 1120. The XeF₂ etch gas is excited by the high heat. Fluorine (F), which does not react with the silicon (Si) component of the silicon oxide (SiO₂) of the quartz mask body 101, is exhausted and recombines to form SiF₄. SiF₄ is a volatile compound that etches the quartz of the mask body 101. On the other hand, the high temperature atmosphere in which the etch gas is excited is not formed at locations outside the area, i.e., the spot, onto which the gallium ions (Ga+) are directed. Thus, the portions of the surface of the body 101 that are not irradiated by the gallium ion (Ga+) beam 1120 are not etched.

Therefore, as shown in FIG. 4C, the gallium ion (Ga+) beam 1120 is moved linearly at a predetermined speed and in such directions that the entire region of the imaginary correction pattern 106 is scanned. Note, one dose of the gallium ion (Ga+) beam corresponds to a depth to which the entire region is uniformly etched over one entire scan. Therefore, the desired depth to which the quartz mask body 101 is etched is established by controlling the FIB system to provide an appropriate number of doses.

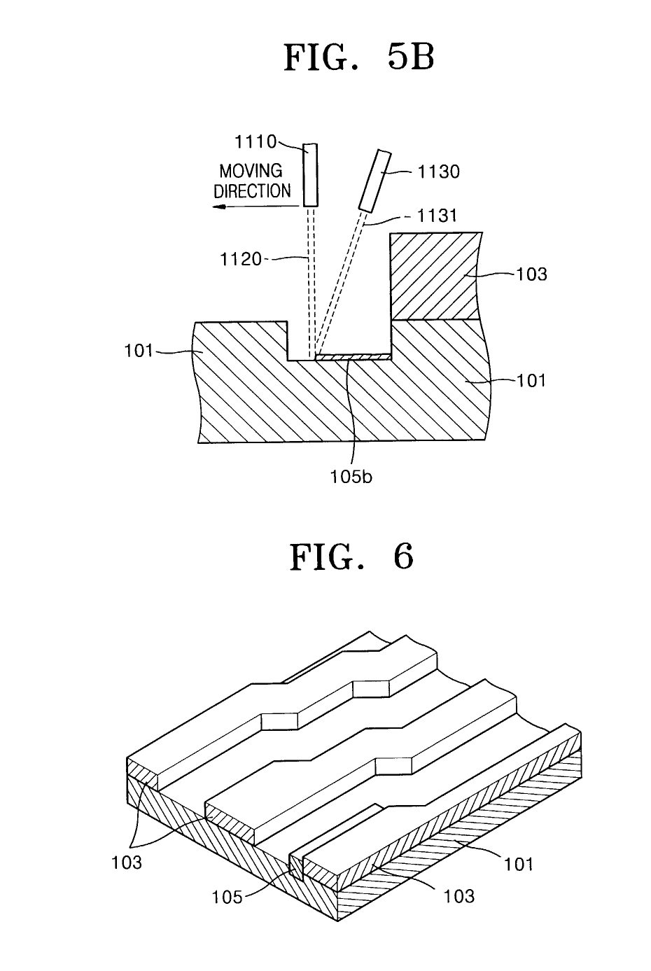

Referring to FIGS. 5A and 5B, which illustrate step S3 of FIG. 1B, the material forming the shifter 105b is subsequently deposited in the recess 105a. The material of the shifter 105b has a property by which the phase of the optical wavelength of light transmitted therethrough is shifted by 180°. As mentioned earlier, a GaₓC_{y} compound is preferably used as the material of the shifter 105b. A method for forming the GaₓC_{y} compound in the recess 105a is similar to the above-mentioned etching method. That is, the GaₓC_{y} compound is formed by using a predetermined focused ion beam (FIB) as an induction beam and by depositing material in the recess 105a by scanning the recess 105a.

That is, referring to FIG. 5B, the gallium ion (Ga+) FIB 1120 is scanned over the recess 105a to again create a high temperature deposition atmosphere instantly within any spot irradiated by the FIB 1120. At the same time, hydrocarbon 1131 (CₓH_{y}) is sprayed by an apparatus 1130 onto the spot irradiated by the FIB 1120. As a result, the hydrocarbon 1131 is dissociated into micron-sized carbon (C) powder, and the carbon (C) reacts with the gallium ions (Ga+) to form GaₓC_{y}, whereby the GaₓC_{y} compound fills the recess 105a.

The ion beam 1120 is moved linearly at a predetermined speed and in such directions that the entire area of the recess 105a is scanned. In this way, the shifter 105b can be formed using a spot deposition method. More specifically, the GaₓC_{y} compound will be formed to a predetermined uniform thickness once the entire area of the recess 105a has been scanned one time. The scanning process is repeatedly performed until the shifter 105b is formed to a thickness that will provide the required phase shifting effect. That is, the thickness of the phase shifter 105b required for effecting the desired magnitude of phase shifting is determined. Then, the number of times that the region of the imaginary correction pattern 106 is scanned is determined by dividing the determined thickness required for phase shifting by the predetermined uniform thickness to which the GaₓC_{y} compound will be formed during each scan.

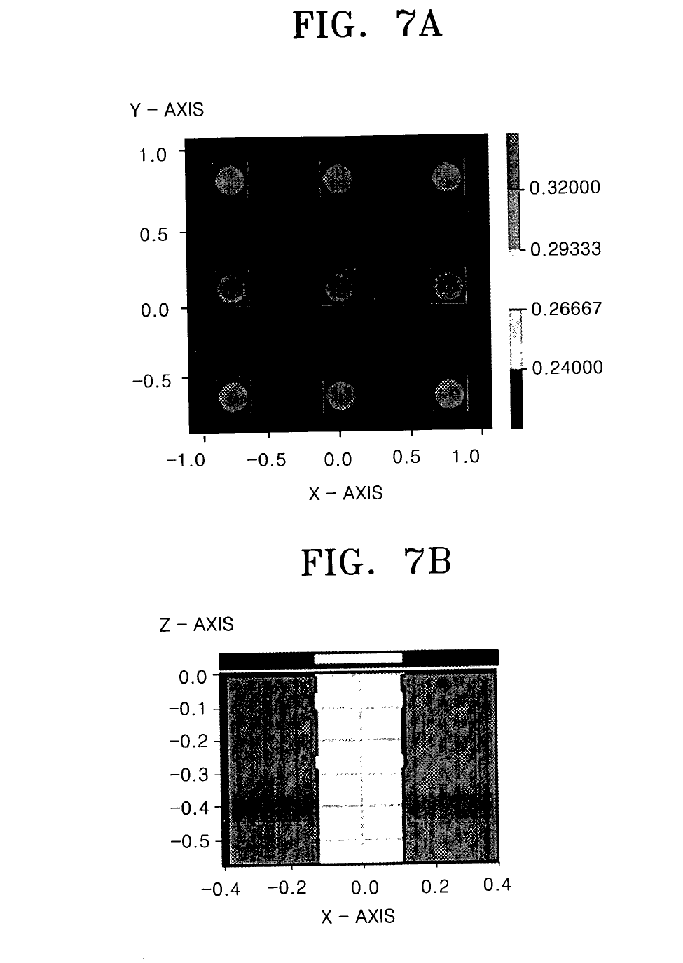

FIG. 6 is a perspective view of a partially repaired phase shift mask pattern in accordance with the present invention. As shown in FIG. 6, the correction pattern 105 is formed in contact with a pattern of the mask layer 103, whereby that portion of the pattern of the mask layer 103 is repaired.

In the method of repairing a phase shift mask pattern according to the present invention, the surface of the mask body 101 (transparent plate) is recessed to a predetermined depth by an etch process, and a shifter having a predetermined thickness is formed in the recess. Thus, virtually any thickness required of the shifter for producing the necessary phase shifting effect can be secured. In addition, the phase shift mask pattern can be used even when there are defects or original manufacturing errors in the phase shift mask pattern. Accordingly, the maintenance and operational costs associated with the phase shift mask are minimized.

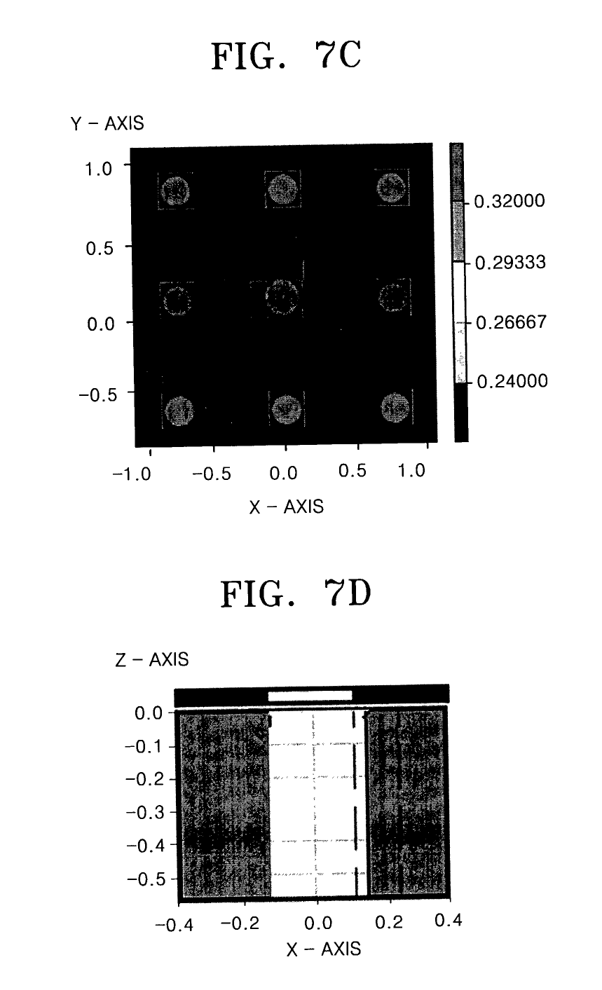

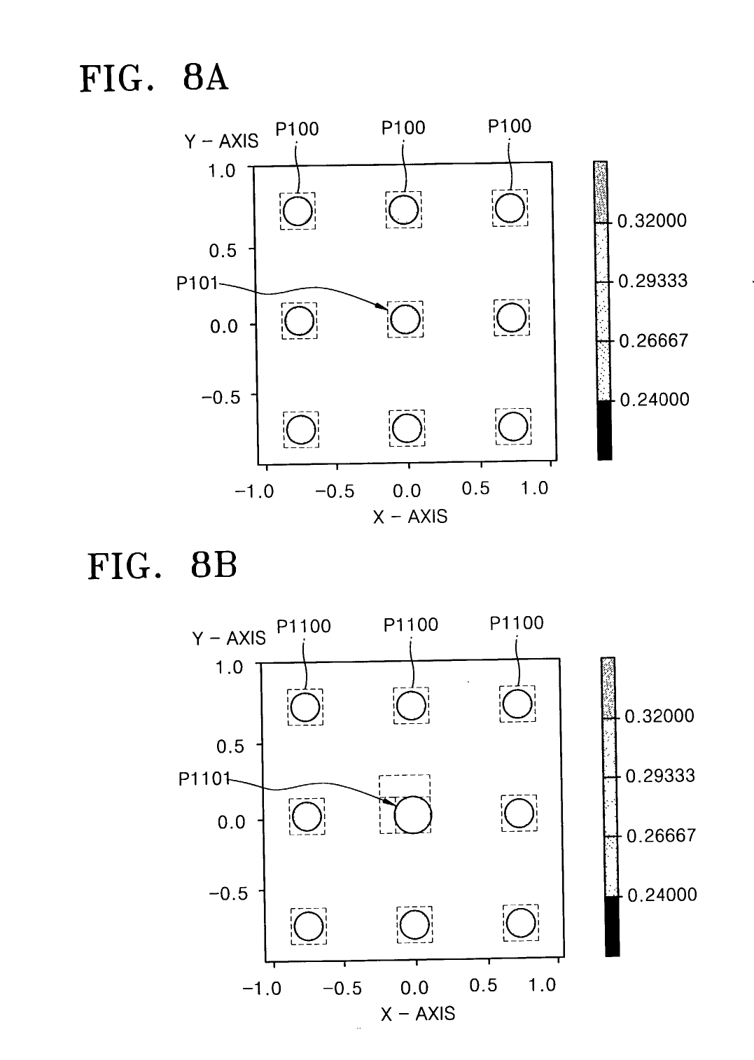

The photos of FIGS. 7A and 7B are cross-sectional photos, taken by a scanning electron microscope (SEM) along X-Y and X-Z axes, respectively, of contact patterns formed on a photoresist using the phase shift mask pattern repaired by the method according to the present invention and of the repaired phase shift mask of the present invention. FIGS. 7C and 7D are photos, taken by an SEM along X-Y and X-Z axes, respectively, of contact patterns formed on a photoresist using the phase shift mask pattern repaired by the conventional method and of the conventionally repaired phase shift mask. Note, identical masks were repaired to produce the masks shown in FIGS. 7B and 7D. FIGS. 8A and 8B are schematic diagrams of the photos of FIGS. 7A and 7C, respectively.

Referring to FIGS. 7A through 7D and FIGS. 8A and 8B, the contact pattern P101 was formed by the patterns of the phase shift mask repaired using the method according to the present invention. The contact pattern P101 has the same shape and size as the adjacent contact patterns P100. However, according to the prior art, although the shape of the contact pattern P1101 is the same as that of adjacent contact patterns P1100, the size of the contact pattern P1101 is different from that of the adjacent contact patterns P1100. As shown in FIG. 7D, according to the prior art, the phase shifting of light through the portion of the repaired contact pattern is not complete. Thus, the contract patterns cannot all be formed to the desired size.

In addition to a phase shift mask for forming contact patterns, the method of repairing a phase shift mask pattern according to the present invention can be applied to phase shift masks used for forming other patterns in a photolithographic process. For instance, the present invention can be applied to phase shift masks used for forming an active pattern of a semiconductor device having a design rule of less than 0.25 μm, a gate pattern, or a metal wiring pattern.

In the present invention, GaₓC_{y}, MoSiOₓN_{y} or CrF₂ can be used as the material of the shifter 105b. In the latter cases, the ion beam source emits molybdenum (Mo) or chromium (Cr) ions instead of gallium ions (Ga+). When forming an MoSiOₓN_{y} shifter, at least one compound containing silicon (Si), oxygen (O), or nitrogen (N) is used as a deposition source material. When forming a CrF₂ shifter, an element or a compound containing fluorine (F) is used as a deposition source material. The deposition source material may be constituted as a solid-phase micro-powder, a gaseous-phase fluid, or a liquid-phase fluid.

Also, an apparatus other than a focused ion beam (FIB) system may be used to form the shifter. For example, the shifter can be formed using an apparatus for emitting a focused light beam, such as a laser or an X-ray apparatus. In such cases, different deposition source materials may be used.

The method of repairing a phase shift mask pattern according to the present invention and the phase shift mask repaired using the same offer the following advantages.

In the method of repairing a phase shift mask pattern, the surface of the mask body (transparent plate) is recessed adjacent the individual pattern requiring repair, and a shifter having a predetermined thickness is formed in the recess to produce a correction pattern. Accordingly, the thickness of the phase shifter is not limited by the thickness of the mask body. Thus, a correction pattern providing any necessary degree of phase shifting can be realized. In addition, the method of repairing the phase shift mask pattern is relatively easy to execute. Accordingly, masks having pattern errors are not wasted, and the costs associated with manufacturing completely new masks are saved.

Although the present invention has been particularly shown and described with reference to the preferred embodiments thereof, various changes in form and details, as will be apparent to those skilled in the art, may be made to the preferred embodiments without departing from the spirit and scope of the invention as defined by the appended claims.

What is claimed is:

1. A method of repairing a phase shift mask for use in photolithography, the phase shift mask having a mask body in the form of a plate of light-transmitting material, and a patterned mask layer disposed on a surface of the mask body, said method comprising:
a) devising an imaginary correction pattern on the basis of the patterned mask layer;
b) etching the surface of the mask body adjacent the mask layer over a region corresponding to the imaginary correction pattern to thereby form a recess in the mask body; and
c) depositing a phase-shifting material in the recess to form a phase shifter in contact with the mask layer.

2. The method of claim 1, wherein a) comprises: scanning the mask layer with light to discern an image of the pattern of the mask layer, and comparing the image of the pattern of the mask layer with a memorized ideal pattern.

3. The method of claim 2, wherein the scanning of the mask layer comprises scanning the layer with a focused ion beam (FIB).

4. The method of claim 3, wherein b) comprises: forming an atmosphere of an etch gas over the mask body, and directing a focused ion beam (FIB) through the atmosphere and onto the mask body.

5. The method of claim 4, wherein b) also comprises scanning the focused ion beam across a region of the mask body corresponding to the top of the imaginary correction pattern.

6. The method of claim 4, wherein the focused ion beam is a focused ion beam (FIB) of gallium ions (Ga+).

7. The method of claim 4, wherein the etch gas is XeF₂.

8. The method of claim 1, wherein c) comprises: emitting an induction beam towards the recess, and spraying a source of deposition material onto the induction beam.

9. The method of claim 8, wherein the induction beam is a focused ion beam.

10. The method of claim 9, wherein the focused ion beam is a focused ion beam (FIB) of gallium ions (Ga+).

11. The method of claim 8, wherein the deposition source material comprises a source of carbon.

12. The method of claim 11, wherein the deposition source material comprises a hydrocarbon (CₓH_{y}).

13. The method of claim 8, wherein the phase shifting material is a GaₓC_{y} compound.

14. The method of claim 8, wherein the phase shifting material comprises an MoSiOₓN_{y} compound.

15. The method of claim 8, wherein the phase shifting material comprises CrF₂.

16. A phase shift mask comprising: a mask body in the form of a transparent plate, a mask layer including a pattern of opaque material disposed on a surface of the mask body, and a correction pattern comprising a recess in said surface of the mask body adjacent said mask layer and a shifter of phase-shifting material occupying said recess and disposed in contact with said mask layer.

17. The mask of claim 16, wherein said mask body is of quartz.

18. The mask of claim 16, wherein said mask layer includes an at least partly opaque layer for phase shifting.

19. The mask of claim 16, wherein said phase-shifting material is a GaₓC_{y} compound.

20. The mask of claim 16, wherein said phase-shifting material comprises a material selected from the group consisting of MoSiOₓN_{y} compounds and CrF₂.
